(19) United States
(12) Patent Application Publication
(10) Pub. No.: US 2026/0302932 A1
(43) Pub. Date: Oct. 1, 2026

(54) CIRCUIT CONFIGURED TO CONTROL A POWER CIRCUIT WITH A HALF-BRIDGE TOPOLOGY

(71) Applicant: STMicroelectronics International N.V., Geneva (CH)

(72) Inventors: Vincent ONDE, Fuveau (FR); Jean-Francois LINK, Trets (FR); Charles AUBENAS, Paris (FR)

(73) Assignee: STMicroelectronics International N.V., Geneva (CH)

(21) Appl. No.: 19/575,743

(22) Filed: Mar. 23, 2026

(30) Foreign Application Priority Data
Mar. 31, 2025 (FR) FR2503284

(51) Int. Cl. H02M 1/32; H02M 1/00; H02M 3/158

(52) U.S. Cl. CPC H02M 1/32; H02M 1/0009; H02M 3/158

(57) ABSTRACT

A microcontroller includes a control circuit configured to control a power circuit having a half-bridge topology. The power circuit is configured to supply a load. The microcontroller further includes a current-monitoring circuit configured to monitor a current supplying the load from the power circuit. The control circuit is configured to control the power circuit according to the monitored current with respect to at least one threshold.

### BACKGROUND

### Technical Filed

Embodiments and implementations relate to power circuits, in particular power circuits having a half-bridge topology.

### Description of the Related Art

A power circuit having a half-bridge topology includes two switches connected in series between two reference nodes, for example between a first reference node configured to receive a supply voltage and a second reference node connected to earth.

Half-bridge topology has a node, called a midpoint, between the two switches. This midpoint is used as the output of the power circuit.

The switches are configured to alternate their state in order to convert a direct current into an alternating current, or to modulate the energy supplied to a load. The half-bridge switches are actuated in such a way that they have an opposite state to each other.

A half-bridge topology can be based on a silicon carbide technology (also designated by the chemical formula “SiC”).

For example, a half-bridge topology may include insulated-gate field-effect transistors (also referred to by the abbreviation “MOSFET” from the English “Metal-Oxide-Semiconductor Field-Effect Transistor”) made of silicon carbide. Such transistors are also referred to as “SiC MOSFET.”

In a variant, the half-bridge topology may include insulated-gate bipolar transistors (also referred to by the abbreviation “IGBT” from the English “Insulated-Gate Bipolar Transistor”).

The structure of an “Sic MOSFET” type transistor incorporates an anti-parallel diode made of silicon carbide. In addition, an anti-parallel diode can also be used in parallel with an IGBT transistor.

An anti-parallel diode is a diode connected in parallel but with the opposite polarity to the transistor. The anti-parallel diode provides a current path when the power transistor is in an off state. This current path is used to protect the power transistor from overvoltages.

However, under certain conditions, in particular when the power stage is switched off, a current, a so-called positive overcurrent, much greater than a nominal current, may pass through the anti-parallel diodes, going to a positive supply bus. This current can reduce the life of the anti-parallel diodes.

To improve the life of the anti-parallel diodes, the anti-parallel diodes are generally oversized to withstand such positive overcurrent. However, such a solution has the disadvantage of entailing a relatively high additional cost.

In addition, this positive overcurrent may also damage other electronic components due to overvoltage. Indeed, the positive overcurrent may damage, for example, a capacitive element disposed between the terminals of the power circuit.

There is a need to propose a solution to improve the control of a power circuit.

### BRIEF SUMMARY

According to one aspect, a microcontroller is proposed including a control circuit configured to control a power circuit having a half-bridge topology, the power circuit being configured to supply a load,
the microcontroller further including a current monitoring circuit configured to monitor a current between the load and the power circuit,
and wherein the control circuit is configured to control the power circuit according to the monitored current with respect to at least one threshold.

Such a microcontroller is configured to improve the control of the power circuit by adapting the control of the power circuit according to the magnitude of a monitored current, with respect to at least one threshold.

Advantageously, the control circuit is configured to control an upper transistor and a lower transistor of the power circuit, the upper transistor and the lower transistor being arranged in series between two terminals of a power source. or example, the upper transistor and the lower transistor are “IGBT” transistors or transistors of the “SiC MOSFET” type. Anti-parallel diodes can be associated with these transistors.

Preferably, the monitoring circuit is configured to detect a positive overcurrent when the monitored current exceeds a first threshold. Advantageously, the control circuit is configured to, when a positive overcurrent is detected −in particular when the current is entering the power circuit from the load−, switch the lower transistor on and the upper transistor off.

A positive overcurrent can for example occur when the load supplied by the power circuit, for example a motor, is overloaded or when a short-circuit occurs on the supply lines of this load. By switching the lower transistor on, the anti-parallel diode associated with the upper transistor can be bypassed. This reduces the stress on the anti-parallel diode associated with the upper transistor. The transistors can thus better withstand the positive overcurrent.

In an advantageous embodiment, the monitoring circuit is configured to compare a voltage representative of the monitored current with a first voltage threshold, the current monitoring circuit is configured to detect a positive overcurrent when the voltage representative of the monitored current is greater than the first voltage threshold.

Such a control circuit makes it possible to protect the anti-parallel diodes from positive overcurrent by creating a current path bypassing the anti-parallel diode of the upper transistor to reduce an electrical stress on the anti-parallel diode of the upper transistor.

Advantageously, the monitoring circuit is configured to detect a negative overcurrent when the monitored current is less than a second threshold, the control circuit being configured to, when a negative overcurrent is detected −in particular when the current is exiting from the power circuit to the load−, switch the lower transistor off and the upper transistor on.

Advantageously, the monitoring circuit is configured to compare a voltage representative of the monitored current with a second voltage threshold, the current monitoring circuit is configured to detect a negative overcurrent when the voltage representative of the monitored current is less than the second voltage threshold.

Preferably, the control circuit is configured to control the power circuit according to a normal operating mode in the absence of a positive overcurrent and to control the power circuit according to a protective operating mode as soon as a positive overcurrent is detected. Advantageously, in the protective operating mode, the control circuit is configured to switch the lower transistor on and the upper transistor off as long as the positive overcurrent is detected.

Advantageously, in the protective operating mode, the control circuit is also configured to, when a negative overcurrent is detected, switch the lower transistor on and the upper transistor off.

In an advantageous embodiment, the control circuit is configured to control the power circuit according to the protective operating mode at least until the positive overcurrent conditions have disappeared before controlling the power circuit according to the normal operating mode. Thus, the control circuit can be configured to control the power circuit in the protective operating mode until the energy present in the load is discharged. The power circuit can then be reset when the positive overcurrent conditions have disappeared, once reset the power circuit is controlled by the control circuit according to the normal operating mode.

Advantageously, the control circuit is configured to control the power circuit according to the normal operating mode after the protective operating mode from a new counting cycle of a counter of the microcontroller used to perform a pulse width modulation of the control signals generated by the control circuit to control the power circuit.

This makes it possible to have non-truncated pulse width modulation cycles, and therefore a good duty cycle, from the start of the transition to normal operating mode.

In an advantageous embodiment, the first threshold is set to different values for the normal operating mode and for the protective operating mode. Advantageously, the value of the first threshold for the protective operating mode is less than the value of the first threshold for the normal operating mode. Preferably, the values of the first threshold are stored in different registers for each operating mode.

Advantageously, the second threshold is set to different values for the normal operating mode and for the protective operating mode, and wherein the value of the second threshold for the protective operating mode is greater than the value of the second threshold for the normal operating mode. Preferably, the values of the second threshold are stored in different registers for each operating mode.

Preferably, the control circuit includes:
a first circuit configured to generate control signals for the power circuit for the normal operating mode, and
a second circuit configured to generate control signals for the power circuit for the protective operating mode.

By using one circuit to generate the control signals for the normal operating mode and another circuit to generate the control signals for the protective operating mode, it is possible to react quickly to positive overcurrents by controlling the power circuit according to the protective operating mode when a positive overcurrent is detected.

Using a hardware solution rather than a software solution to switch to protective operating mode also allows a quick reaction to positive overcurrents.

Advantageously, the control circuit includes a multiplexer configured to select the control signals to be used to control the power circuit according to the mode of operation implemented by the control circuit.

According to another aspect, a method is proposed for controlling a power circuit having a half-bridge topology, the power circuit being configured to supply a load, the method including:
monitoring, by a current-monitoring circuit, a current supplying the load from the power circuit,
controlling the power circuit by a control circuit according to the monitored current with respect to at least one threshold.

In one embodiment, a system includes a half bridge circuit configured to supply a load and a microcontroller including a control circuit. The control circuit includes a first circuit configured to generate first signals controlling the power circuit for the normal operating mode, a second circuit configured to generate second signals controlling the power circuit for the protective operating mode, and a multiplexer including a first input receiving the first signals, a second input receiving the second signals, and a selection input. The control circuit includes a monitoring circuit configured to monitor a current between the load and the power circuit and having an output coupled to the selection input.

### BRIEF DESCRIPTION OF THE SEVERAL VIEWS OF THE DRAWINGS

Other advantages and features of the disclosure will become apparent upon examining the detailed description of non-limiting embodiments, and from the appended drawings wherein:

FIG. 1 is a schematic illustration of an electronic system including a microcontroller, a power circuit, and a current monitoring circuit, in accordance with one embodiment;

FIG. 2 is an illustration of a power circuit including a half-bridge topology, in accordance with one embodiment; and

FIG. 3 illustrates a timing chart of an implementation of a method for controlling a power circuit with half-bridge topology.

### DETAILED DESCRIPTION

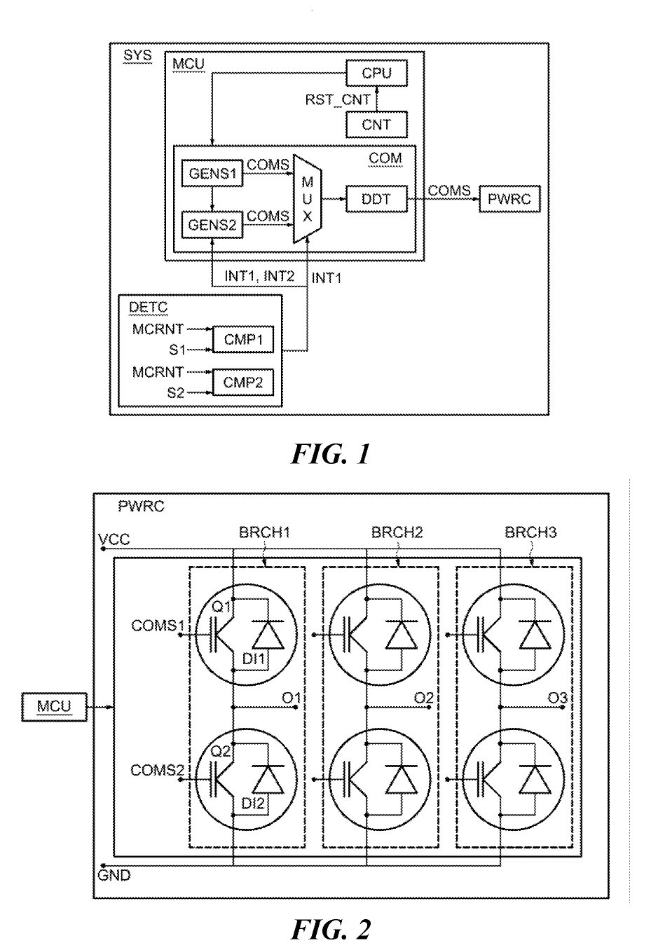

FIG. 1 schematically illustrates an embodiment of an electronic system SYS including a microcontroller MCU, a power circuit PWRC as well as a current monitoring circuit DETC.

The power circuit PWRC has a half-bridge topology. The power circuit can be an output power stage of an inverter or a DC-DC converter for example.

FIG. 2 shows a power circuit PWRC having a half-bridge topology. The power circuit PWRC may have several phase branches in order to generate several phases of an output signal. For example, in FIG. 2, the power circuit has three phase branches BRCH1, BRCH2, BRCH3.

In particular, in the half-bridge topology, each phase branch includes two switches Q1, Q2 connected in series between two reference nodes, for example between a first reference node configured to receive a supply voltage and a second reference node connected to an earth. Here, the switches are bipolar insulated gate transistors “IGBT.” Nonetheless, in a variant, when the half-bridge topology is here based on a silicon carbide technology (also designated by the chemical formula “SiC”), the switches may be insulated-gate field effect transistors (also designated by the abbreviation “MOSFET” from the English “Metal-Oxide-Semiconductor Field-Effect Transistor”) made of silicon carbide (“SiC MOSFET”).

Half-bridge topology has a node, called a midpoint, between the two switches. This midpoint is used as the output of the power circuit. For example, the branch BRCH1 has an output O1, the branch BRCH2 has an output O2 and the branch BRCH3 has an output O3.

The transistors Q1 and Q2 are controlled by control signals COMS1 and COMS2 respectively so as to alternate their state in order to convert a direct current into an alternating current, or to modulate the energy supplied to a load. The transistors Q1 and Q2 of the half-bridge are therefore controlled so as to have a state opposite to one another.

The transistors Q1, Q2 are respectively associated with an anti-parallel diode DI1, DI2.

Each anti-parallel diode D1, D2 is a diode connected in parallel but in opposite polarity to the transistor Q1, Q2 with which it is associated. Each anti-parallel diode D1, D2 makes it possible to provide a current path when its associated transistor Q1, Q2 is in an off state. This current path protects the transistor Q1, Q2 associated with the anti-parallel diode D1, D2 from overvoltages.

Returning to FIG. 1, the microcontroller MCU includes a control circuit COM configured to control the power circuit PWRC, in particular the transistors Q1, Q2 of the power circuit PWRC.

The current monitoring circuit DETC is configured to monitor a current in the load supplied by the power circuit PWRC. In particular, a current sensor (not shown) can be used to measure the current in the load. The current measurements can then be transmitted to the current-monitoring circuit. For example, the current sensor may be configured to generate a voltage dependent on the current monitored by the current sensor. This voltage can be transmitted to the current-monitoring circuit DETC.

The current-monitoring circuit DETC comprises a first comparator CMP1 configured to compare the current measurements MCRNT with a first threshold S1, in order to detect a positive overcurrent. For example, the first comparator CMP1 can be configured to compare the voltage generated by the current sensor with a first voltage threshold associated with a first current threshold characterizing a positive overcurrent. When the voltage generated by the current sensor is higher than this voltage threshold, a positive overcurrent is detected. The first comparator CMP1 is configured to generate the signal INT1 when a positive overcurrent is detected.

The current-monitoring circuit DETC includes a second comparator CMP2 configured to compare the current measurements MCRNT with a second threshold S2, in order to detect a negative overcurrent. For example, the second comparator CMP2 can be configured to compare the voltage generated by the current sensor with a second voltage threshold associated with a second current threshold characterizing a negative overcurrent. When the voltage generated by the current sensor is less than this voltage threshold, a negative overcurrent is detected. The second comparator CMP2 is configured to generate the signal INT2 when a negative overcurrent is detected.

The control circuit COM can be controlled in a normal operating mode or in a protective operating mode.

In the normal operating mode, the control circuit COM is configured to control the power circuit PWRC according to a desired voltage level at the output of the half-bridge. The half-bridge output voltage level depends on a command COMS (including the control signals COMS1 and COMS2) applied to transistors Q1 and Q2. The command COMS applied to a transistor makes it possible to switch this transistor on or off.

In particular, in the normal operating mode, the control circuit is configured to generate control signals COMS1 and COMS2 to control the transistors Q1, Q2 of the power circuit. These control signals have a sequence of pulses making it possible to alternate between high and low state, in order to switch the transistors Q1 and Q2 on or off. In particular, these COMS control signals are pulse width modulated signals (also referred to by the abbreviation “PWM” from the English “Pulse Width Modulation”). These signals are generated in such a way that, at the output of the phase branch, transitions are made between the supply voltage VDC and a zero voltage of the earth GND.

The protective operating mode is used when a positive overcurrent is detected by the current-monitoring circuit DECT.

More particularly, the control circuit COM includes a circuit GENS1 for generating control signals for the normal operating mode.

This control signal generation circuit GENS1 is configured to generate control signals COMS adapted to control the transistors Q1, Q2 in a normal operation. As seen previously, the control signals COMS are in particular pulse width modulated signals.

A counter CNT is used for pulse width modulation. This counter CNT is configured to increment a value from an initial value to a maximum value at a defined frequency. Once the maximum value is reached, the counter value is reset to its initial value in order to start a new cycle of incrementations. The counter cycle defines the cycle “PWM” of the control signals COMS.

The current-monitoring circuit DETC is configured to generate a signal INT1 when a positive overcurrent is detected. This signal INT1 lets the control circuit COM know that a change to protective operating mode is called for.

In particular, the control circuit COM also includes a control-signal generation circuit GENS2 for the protective operating mode. The circuit GENS2 generating control signals for the protective operating mode is configured to control the power circuit PWRC from the moment a signal INT1 is generated by the current-monitoring circuit DETC in the normal operating mode, i.e., when a positive overcurrent is detected in the normal operating mode.

In particular, the control-signal generation circuit GENS2 for the protective operating mode is configured to generate control signals COMS to control the transistors Q1 and Q2 of the power circuit PWRC in the protective operating mode. In particular, the circuit GENS2 generating control signals for the protective operating mode is configured to generate a control signal COMS1 for controlling the transistor Q1, and a control signal COMS2 for controlling the transistor Q2.

The circuit GENS2 generating control signals for the protective operating mode is configured to generate pulses in the control signal COMS2 when a positive overcurrent is detected in order to switch the transistor Q2 on. This creates a current path to bypass the anti-parallel diode. This makes it possible to reduce the electrical stress on the anti-parallel diode of the transistor Q1 in order to limit a risk of damaging the anti-parallel diode of the transistor Q1. The circuit GENS2 generating control signals for the protective operating mode is also configured to keep the transistor Q2 off when the measured current is not a positive overcurrent.

The circuit GENS2 generating control signals for the protective operating mode is configured to generate pulses in the control signal COMS1 when a negative overcurrent is detected in order to switch the transistor Q1 on. The circuit GENS2 generating control signals for the protective operating mode is also configured to keep the transistor Q1 off when the measured current is not a negative overcurrent.

Such a circuit GENS2 for generating control signals for the protective operating mode is simple to implement and is inexpensive, in particular due to its integration in a microcontroller.

Furthermore, the values of the thresholds S1, S2 used by the comparators CMP1, CMP2 can be dynamically adjusted according to the operating mode used to control the power circuit PWRC (normal operating mode or protective operating mode). The threshold values are defined according to an ability of the anti-parallel diode of the transistor Q1 to resist electrical stress. In the normal operating mode, the threshold used to detect a positive overcurrent is higher than that used to detect a positive overcurrent in the protective operating mode. Furthermore, in the normal operating mode, the threshold for detecting a negative overcurrent is lower than that used for detecting a negative overcurrent in the protective operating mode.

The threshold values can be stored in different registers for each operating mode. These values are transmitted to the comparators of the current-monitoring circuit according to the operating mode used to control the power circuit.

Once the positive overcurrent conditions have disappeared, the power circuit can be reset and be controlled by the control circuit in a normal operating mode. In particular, when the positive overcurrent conditions disappear, the signal INT1 is no longer generated, the power circuit can then be reset once the signal INT1 is no longer generated. The microcontroller can also run a diagnostic function to find the cause of the positive overcurrent in order to eliminate it or at least to verify that changing the control signals of the power circuit actually causes the current to return to a normal level.

In particular, a central processing unit CPU of the microcontroller MCU may be configured to automatically reboot the power circuit PWRC once the positive overcurrent conditions have disappeared.

Advantageously, the central processing unit CPU is configured to wait for a new cycle of the counter CNT used for the pulse width modulation, in particular to define the duty cycle of each pulse, before rebooting the power circuit PWRC. This synchronizes the reboot of the PWRC power circuit with the new cycle of the CNT counter.

In order to detect the new cycle of the CNT counter, the central processing unit is configured to receive a signal RST_CNT re-initializing the counter CNT. This re-initialization signal thus allows the central processing unit to reboot the power circuit once the positive overcurrent conditions have disappeared.

The control circuit COM may also include a multiplexer MUX configured to select the control signals COMS1, COMS2 (COMS) output from the circuit GENS1 f generating control signals or the normal operating mode or the control signals output from the circuit GENS2 generating control signals for the protective operating mode depending on whether the signal INT1 was generated by the current-monitoring circuit during a normal operation mode or not.

In particular, the multiplexer MUX has a first input configured to receive the control signals generated by the circuit GENS1 generating control signals for the normal operating mode.

The multiplexer MUX has a second input configured to receive the control signals generated by the circuit GENS2 generating control signals for the protective operating mode IGC.

The multiplexer MUX also has a selection input configured to receive an INT1 signal to indicate which control signal COMS to use to control the transistors of the power circuit.

The control circuit COM also includes a deadtime-generation circuit DDT. This circuit DDT is configured to generate a dead time DDT_t on the control signals COMS during which no transistor is on on the upper part of one and the same same branch or on the lower part of one and the same same branch, in order to avoid a direct short-circuit through the power transistors of one and the same phase.

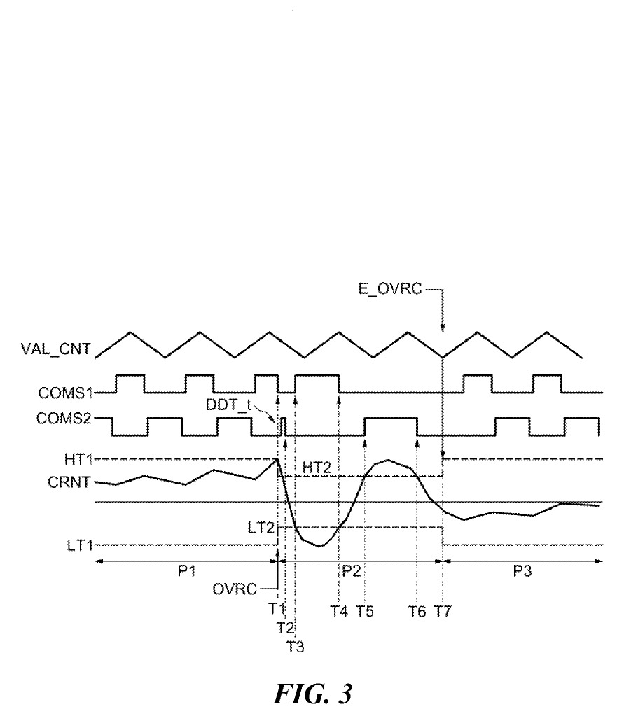

FIG. 3 illustrates a time chart of an implementation of a method for controlling a power circuit PWRC with half-bridge topology.

The signal VAL_CNT corresponds to the value of the counter CNT used for pulse width modulation.

The signal COMS1 corresponds to the control signal COMS controlling the upper transistor Q1.

The signal COMS2 corresponds to the control signal COMS that controls the lower transistor Q2.

The signal CRNT corresponds to the current value in the load measured by the current sensor.

FIG. 3 illustrates the control signals COMS1, COMS_Q2 during a normal operating mode of the power circuit PWRC, during a period P1, then during a protective operating mode OVCM, during a period P2, before returning to a normal operating mode during a period P3.

In particular, the control signals COMS1, COMS2, during a normal operating mode, change from a high state to a low state, and vice versa, according to a pulse width modulation, depending on the desired voltage level at the output of the phase branch.

In the normal operating mode, an upper current threshold HT1 is set to detect positive overcurrents and a lower current threshold LT1 is set to detect negative overcurrents. These current thresholds HT1, LT1 define the voltage thresholds used by the comparators CMP1, CMP2 of the current monitoring circuit DETC.

In this example, the control signal COMS1 of the upper transistor Q1 going into a high state (the upper transistor is then on) causes a positive overcurrent in the load. This positive overcurrent is detected by the current-monitoring circuit DETC.

When the positive overcurrent OVRC is detected, at the time T1, the control circuit COM goes into a protective operating mode for a period P2. In particular, in a first step, the upper transistor Q1 is switched off as the first protective measure and the device then goes into the protective operating mode. In the protective operating mode, the upper current threshold defining a positive overcurrent is lowered to a value HT2 and the lower current threshold defining a negative overcurrent is increased to a value LT2.

In the protective operating mode, the control circuit COM is configured to activate the lower transistor Q2 when the current measured by the current sensor of the current-monitoring circuit DETC is greater than the upper current threshold set in the protective operating mode. In particular, when a positive overcurrent is detected, for example at the times T1 and T5, the control circuit generates a pulse on the control signal COMS2 until the measured current is lower than the upper current threshold HT2, in particular up to the times T2 and T6.

Furthermore, in the protective operating mode, the control circuit COM is configured to activate the upper transistor Q1 when the current measured by the current sensor of the current-monitoring circuit is less than or equal to the lower current threshold. This In particular, when a negative overcurrent is detected, for example at the time T3, the control circuit generates a pulse on the control signal COMS1 until the measured current is greater than the lower current threshold, in particular up to the time T4.

A dead time may also be inserted between the deactivation of one transistor and the activation of the other transistor in order to prevent both transistors from being on simultaneously. For example, in the illustrated implementation, a dead time DDT_t1 is inserted.

Once the positive overcurrent conditions E_OVRC have disappeared, the power circuit PWRC can be reset and controlled according to the normal operating mode from a new cycle of the counter CNT , at the time T7 (period P3).

In one embodiment, a microcontroller includes a control circuit (COM) configured to control a power circuit (PWRC) having a half-bridge topology, the power circuit (PWRC) being configured to supply a load, the microcontroller further including a current-monitoring circuit (DETC) configured to monitor a current between the load and the power circuit (PWRC), and wherein the control circuit (COM) is configured to control the power circuit (PWRC) according to the monitored current with respect to at least one threshold.

The control circuit (COM) is configured to control an upper transistor (Q1) and a lower transistor (Q2) of the power circuit (PWRC), the upper transistor (Q1) and the lower transistor (Q2) being arranged in series between two terminals of a power source (VDC, GND).

The monitoring circuit (DETC) is configured to detect a positive overcurrent when the monitored current exceeds a first threshold (HT1, HT2), and wherein the control circuit (COM) is configured to, when a positive overcurrent is detected, switch the lower transistor (Q2) on and switching the upper transistor (Q1) off.

The monitoring circuit (DETC) is configured to compare a voltage representative of the monitored current to a first voltage threshold, the current monitoring circuit (DETC) is configured to detect a positive overcurrent when the voltage representative of the monitored current is greater than the first voltage threshold.

The monitoring circuit (DETC) is configured to detect a negative overcurrent when the monitored current is less than a second threshold, the control circuit (COM) being configured to, when a negative overcurrent is detected, switch the lower transistor (Q2) off and the upper transistor (Q1) on.

The monitoring circuit (DETC) is configured to compare a voltage representative of the monitored current with a second voltage threshold, and the current monitoring circuit (DETC) is configured to detect a negative overcurrent when the voltage representative of the monitored current is less than the second voltage threshold.

The control circuit (COM) is configured to control the power circuit (PWRC) according to a normal operating mode in the absence of a positive overcurrent and to control the power circuit (PWRC) according to a protective operating mode as soon as a positive overcurrent is detected, and wherein, in the protective operating mode, the control circuit is configured to switch the lower transistor (Q2) on and the upper transistor (Q1) off as long as the positive overcurrent is detected.

In the protective operating mode, the control circuit (COM) is also configured to, when a negative overcurrent is detected, switch the lower transistor (Q2) on and the upper transistor (Q1) off.

The control circuit (COM) is configured to control the power circuit (PWRC) according to the protective operating mode at least until the positive overcurrent conditions have disappeared before controlling the power circuit according to the normal operating mode.

The control circuit (COM) is configured to control the power circuit (PWRC) according to the normal operating mode after the protective operating mode from a new counting cycle of a counter (CNT) of the microcontroller used to perform a pulse width modulation of the control signals generated by the control circuit to control the power circuit.

The first threshold is set to different values for the normal operating mode and for the protective operating mode, and wherein the value of the first threshold for the protective operating mode is less than the value of the first threshold for the normal operating mode.

The second threshold is set to different values for the normal operating mode and for the protective operating mode, and wherein the value of the second threshold for the protective operating mode is greater than the value of the second threshold for the normal operating mode.

The control circuit includes: a first circuit (GENS1) configured to generate signals controlling the power circuit for the normal operating mode, and a second circuit (GENS2) configured to generate signals controlling the power circuit for the protective operating mode.

The control circuit (COM) includes a multiplexer (MUX) configured to select the control signals to be used to control the power circuit according to the operating mode implemented by the control circuit.

In one embodiment, a method for controlling a power circuit (PWRC) having a half-bridge topology, the power circuit (PWRC) being configured to supply a load, the method includes monitoring, by a current monitoring circuit (DETC), a current supplying the load from the power circuit (PWRC), controlling the power circuit by a control circuit according to the monitored current with respect to at least one threshold.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A microcontroller comprising:
a control circuit configured to control a power circuit having a half-bridge topology, the power circuit being configured to supply a load; and
a current-monitoring circuit configured to monitor a current between the load and the power circuit,
wherein the control circuit is configured to control the power circuit according to the monitored current with respect to at least one threshold.

2. The microcontroller according to claim 1, wherein the control circuit is configured to control an upper transistor and a lower transistor of the power circuit, the upper transistor and the lower transistor being arranged in series between two terminals of a power source.

3. The microcontroller according to claim 2, wherein the monitoring circuit is configured to detect a positive overcurrent when the monitored current exceeds a first threshold, and wherein the control circuit is configured to, when a positive overcurrent is detected, switch the lower transistor on and switching the upper transistor off.

4. The microcontroller according to claim 3, wherein the monitoring circuit is configured to compare a voltage representative of the monitored current to a first voltage threshold, the current monitoring circuit is configured to detect a positive overcurrent when the voltage representative of the monitored current is greater than the first voltage threshold.

5. The microcontroller according to claim 1, wherein the monitoring circuit is configured to detect a negative overcurrent when the monitored current is less than a second threshold, the control circuit being configured to, when a negative overcurrent is detected, switch the lower transistor off and the upper transistor on.

6. The microcontroller according to claim 5, wherein the monitoring circuit is configured to compare a voltage representative of the monitored current with a second voltage threshold, and the current monitoring circuit is configured to detect a negative overcurrent when the voltage representative of the monitored current is less than the second voltage threshold.

7. The microcontroller according to claim 2, wherein the control circuit is configured to control the power circuit according to a normal operating mode in the absence of a positive overcurrent and to control the power circuit according to a protective operating mode as soon as a positive overcurrent is detected,
and wherein, in the protective operating mode, the control circuit is configured to switch the lower transistor on and the upper transistor off as long as the positive overcurrent is detected.

8. The microcontroller according to claim 7, wherein, in the protective operating mode, the control circuit is also configured to, when a negative overcurrent is detected, switch the lower transistor on and the upper transistor off.

9. The microcontroller according to claim 7, wherein the control circuit is configured to control the power circuit according to the protective operating mode at least until the positive overcurrent conditions have disappeared before controlling the power circuit according to the normal operating mode.

10. The microcontroller according to claim 9, wherein the control circuit is configured to control the power circuit according to the normal operating mode after the protective operating mode from a new counting cycle of a counter of the microcontroller used to perform a pulse width modulation of the control signals generated by the control circuit to control the power circuit.

11. The microcontroller according to claim 7, wherein the first threshold is set to different values for the normal operating mode and for the protective operating mode, and wherein the value of the first threshold for the protective operating mode is less than the value of the first threshold for the normal operating mode.

12. The microcontroller according to claim 7, wherein the second threshold is set to different values for the normal operating mode and for the protective operating mode, and wherein the value of the second threshold for the protective operating mode is greater than the value of the second threshold for the normal operating mode.

13. The microcontroller according to claim 7, wherein the control circuit includes:
a first circuit configured to generate signals controlling the power circuit for the normal operating mode, and
a second circuit configured to generate signals controlling the power circuit for the protective operating mode.

14. The microcontroller according to claim 13, wherein the control circuit includes a multiplexer configured to select the control signals to be used to control the power circuit according to the operating mode implemented by the control circuit.

15. A method for controlling a power circuit having a half-bridge topology, the power circuit being configured to supply a load,
the method comprising:
monitoring, by a current monitoring circuit, a current supplying the load from the power circuit; and
controlling the power circuit by a control circuit according to the monitored current with respect to at least one threshold.

16. The method of claim 15, further comprising controlling, with the control circuit, an upper transistor and a lower transistor of the power circuit, the upper transistor and the lower transistor being arranged in series between two terminals of a power source.

17. The method of claim 16, further comprising:
detecting, with the monitoring circuit, a positive overcurrent when the monitored current exceeds a first threshold; and
switching, with the control circuit when a positive overcurrent is detected, the lower transistor on and switching the upper transistor off.

18. The method of claim 17, further comprising:
comparing, with the monitoring circuit, a voltage representative of the monitored current to a first voltage threshold; and
detecting, with the current monitoring circuit, a positive overcurrent when the voltage representative of the monitored current is greater than the first voltage threshold.

19. A system, comprising:
a half bridge circuit configured to supply a load;
a microcontroller including a control circuit, the control circuit including:
a first circuit configured to generate first signals controlling the power circuit for the normal operating mode;
a second circuit configured to generate second signals controlling the power circuit for the protective operating mode;
a multiplexer including a first input receiving the first signals, a second input receiving the second signals, and a selection input;
a monitoring circuit configured to monitor a current between the load and the power circuit and having an output coupled to the selection input.

20. The system of claim 19, wherein the control circuit is configured to control the power circuit according to the monitored current with respect to at least one threshold.
